(19) United States
(12) Patent Application Publication
(10) Pub. No.: US 2026/0190670 A1
(43) Pub. Date: Jul. 2, 2026

(54) DISPLAY DEVICE

(71) Applicant: LG Display Co., Ltd., Seoul (KR)

(72) Inventors: SungKi Kim, Paju-si (KR); JungJune Kim, Paju-si (KR); SeokWoo Son, Paju-si (KR); Harin Kim, Paju-si (KR)

(73) Assignee: LG Display Co., Ltd., Seoul (KR)

(21) Appl. No.: 19/400,420

(22) Filed: Nov. 25, 2025

(30) Foreign Application Priority Data
Dec. 26, 2024 (KR) 10-2024-0197501

(51) Int. Cl. H10K 59/124; H10K 59/121; H10K 59/123; H10K 59/126

(52) U.S. Cl. CPC H10K 59/124; H10K 59/1213; H10K 59/1216; H10K 59/123; H10K 59/126

(57) ABSTRACT

A display device is provided, which includes first to third passivation layers, wherein the second passivation layer is not exposed to an outside by the first passivation layer and the third passivation layer, and wherein a dielectric constant of the second passivation layer is higher than a dielectric constant of each of the first passivation layer and the third passivation layer.

### CROSS-REFERENCE TO RELATED APPLICATION

This application claims the benefit of the Republic of Korea Patent Application No. 10-2024-0197501, filed on Dec. 26, 2024, which is hereby incorporated by reference in its entirety.

### BACKGROUND

### Field of Technology

The present disclosure relates to a display device.

### Description of the Related Art

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required, and power consumption is advantageous. In addition, the organic light emitting display device has an advantage of being driven with a low DC voltage, having a fast response speed, and especially low manufacturing cost.

Recently, research has been conducted to stably form a storage capacitor while securing a capacity of the storage capacitor.

### SUMMARY

The present disclosure has been made in view of the above problems, and it is an aspect of the present disclosure to provide a display device with improved capacity and with potential structural defects in storage capacitors prevented or mitigated.

To achieve these and other advantages and in accordance with an aspect of the present disclosure, as embodied and broadly described herein, a display device includes a light shielding layer on a substrate, a driving thin film transistors on the light shielding layer, and a passivation layer on the driving thin film transistor, the passivation layer including a first passivation layer on the driving thin film transistor, a second passivation layer on the first passivation layer, and a third passivation layer on the second passivation layer, wherein the second passivation layer is not exposed to an outside by the first passivation layer and the third passivation layer, and wherein a dielectric constant of the second passivation layer is higher than a dielectric constant of each of the first passivation layer and the third passivation layer.

It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description explain various principles of the disclosure.

FIG. 1 is a plan view of a display device according to an example embodiment of the present disclosure.

FIG. 2 is a plan view of a sub-pixel according to an example embodiment of the present disclosure.

FIG. 3 is a cross-sectional view taken along line A-A′ in FIG. 2.

FIG. 4 is a cross-sectional view taken along line B-B′ in FIG. 2.

FIG. 5 is a cross-sectional view taken along line C-C′ in FIG. 2.

Throughout the drawings and the detailed description, unless otherwise described, the same drawing reference numerals should be understood to refer to the same elements, features, and/or structures. The relative size and depiction of these elements may be exaggerated for clarity, illustration, and/or convenience.

### DETAILED DESCRIPTION

Reference will now be made in detail to embodiments of the present disclosure, examples of which may be illustrated in the accompanying drawings. The progression of processing steps and/or operations described is an example, and the sequence of steps and/or operations is not limited to that set forth herein and may be changed as is known in the art, with the exception of steps and/or operations specified as necessarily occurring in a particular order. Names of the respective elements used in the following explanations may be selected only for convenience of writing the specification and may thus be different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be more thorough and complete, and more fully convey the scope of the present disclosure to those skilled in the art. Further, a protected scope of the present disclosure may be defined by the accompanying claims and their equivalents.

A shape, a size, a ratio, an angle, and a number disclosed in the accompanying drawings for describing the examples of the present disclosure are merely illustrative, and the present disclosure is thus not limited to the illustrated details. Unless stated otherwise, like reference numerals refer to like elements throughout the specification. In the following description, where the detailed description of the relevant known function or configuration may unnecessarily obscure an aspect or feature of the present disclosure, such detailed description may be omitted. Where terms like “comprise,” “have,” and “include” are used in the present disclosure, another portion may be added unless a more specific term like “only˜” is used. The terms of a singular form may include plural forms, and vice versa, unless referred to the contrary.

In interpreting the components, they are to be interpreted as including an error range even if there is no separate explicit description of an error range.

In describing a position relationship, for example, where the position relationship is described as “upon˜,” “above˜,” “below˜,” and “next to˜,” one or more portions may be disposed between two other portions unless a more specific term like “just” or “direct” is used. Such terms as “below,” “lower,” “above,” “upper,” and the like may be used herein to describe a relationship between elements as illustrated in the drawings. It should be understood that the terms are spatially relative and based on the orientation depicted in the drawings.

A description of a time relationship may include a case in which the temporal precedence relationship is described as “after,” “following,” “before,” etc., and is not continuous unless a more specific term like “right away” or “directly” is used.

Although terms like “first” and “second” may be used to describe various components, these components are not limited by these terms. These terms are used only to refer to one component separately from another. Therefore, a first component mentioned below may be a second component, and vice versa, within a technical idea of a present disclosure.

It should be understood that, although such terms as “first,” “second,” “A,” “B,” “(a),” and “(b),” may be used herein to describe various elements, these elements should not be limited by these terms. These terms are only used to refer to one element separately from another. For example, a first element could be termed a second element, and similarly, a second element could be termed a first element, without departing from the scope of the present disclosure.

Features of each of the various examples of the present disclosure may be partially or entirely coupled or combined with each other, technically various interworking and driving are possible, and each of the examples may be independently implemented with respect to each other or may be implemented together in an associated relationship.

Hereinafter, one or more example embodiments of the present disclosure will be described in detail with reference to the accompanying drawings.

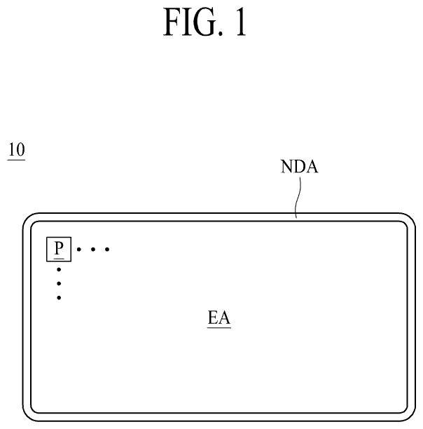

FIG. 1 is a plan view of a display device 10 according to an example embodiment of the present disclosure.

As shown in FIG. 1, the display device 10 according to an example embodiment of the present disclosure may include a display area EA and a non-display area NDA surrounding the display area EA. The display area EA is an area in which an image may be displayed, and the non-display area NDA is an area in which an image is not displayed.

The display area EA may include a plurality of pixels P. The plurality of pixels P may be arranged in a matrix form consisting of a plurality of rows and columns. In addition, the non-display area NDA may include a plurality of wirings, pads, driving circuits, etc., for driving the plurality of pixels P.

Each of the plurality of pixels P may include a plurality of sub-pixels SP. For example, one pixel P may include a red sub-pixel, a green sub-pixel, and a blue sub-pixel, but is not limited thereto.

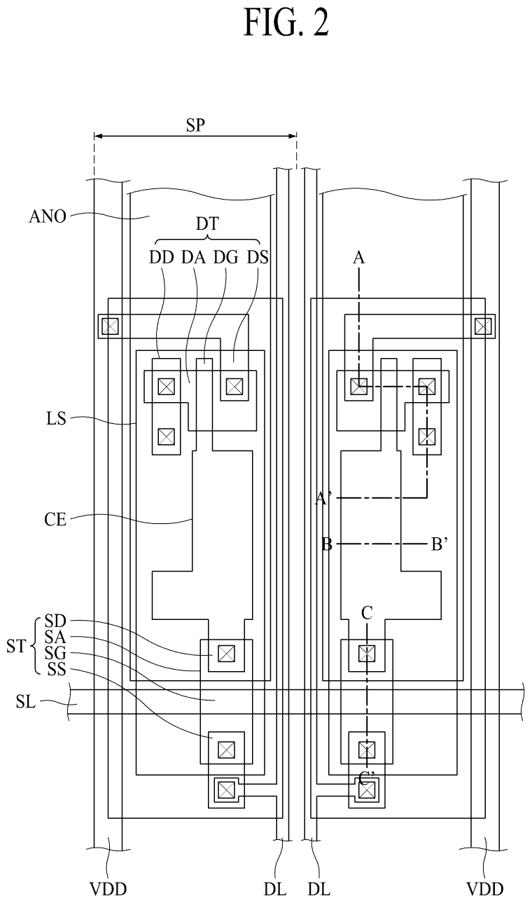

FIG. 2 is a plan view of a sub-pixel SP according to an example embodiment of the present disclosure.

As shown in FIG. 2, a scan line SL, a data line DL, and a driving voltage line VDD may be disposed on a substrate. The scan line SL may extend in a first direction, and the data line DL and the driving voltage line VDD may extend in a second direction crossing the first direction. For example, the first direction may be a horizontal direction, and the second direction may be a vertical direction, but the present disclosure is not limited thereto. One sub-pixel SP may include the scan line SL, the data line DL, and the driving voltage line VDD.

A light shielding layer LS, a switching thin film transistor ST, a driving thin film transistor DT, a capacitor electrode CE, and an anode ANO may be disposed in one sub-pixel SP. The driving voltage line VDD may apply a high potential voltage to the anode ANO.

The light shielding layer LS may be disposed on a substrate. Since the light shielding layer LS is not connected to signal lines such as the scan line SL, the data line DL, and the driving voltage line VDD, a function of supplying a voltage to other components may not be performed.

To prevent or protect a semiconductor layer SA of the switching thin film transistor ST and a semiconductor layer DA of the driving thin film transistor DT from being affected by external light, the light shielding layer LS may be disposed in an area overlapping the semiconductor layer SA of the switching thin film transistor ST and the semiconductor layer DA of the driving thin film transistor DT. In addition, the light shielding layer LS may overlap other components of the switching thin film transistor ST and the driving thin film transistor DT in addition to the semiconductor layer SA of the switching thin film transistor ST and the semiconductor layer DA of the driving thin film transistor DT, but is not limited thereto. For example, FIG. 2 discloses a structure in which the light shielding layer LS overlaps the scan line SL and the anode ANO, but is not limited thereto.

The light shielding layer LS may include a conductive material capable of blocking light. For example, the light shielding layer LS may be formed of an opaque metal material such as aluminum (Al), silver (Ag), copper (Cu), molybdenum (Mo), titanium (Ti), tungsten (W), or chromium (Cr), or an alloy thereof.

The switching thin film transistor ST may be disposed in an area where the scan line SL and the data line DL cross each other. The switching thin film transistor ST may overlap the light shielding layer LS. The switching thin film transistor ST may select a pixel to be driven by applying a data signal to the driving thin film transistor DT.

The switching thin film transistor ST may include a switching gate electrode SG, a switching semiconductor layer SA, a switching source electrode SS, and a switching drain electrode SD. The switching thin film transistor ST may be connected to the scan line SL and the data line DL. Specifically, the switching gate electrode SG may branch from the scan line SL or may be a part of the scan line SL as shown in FIG. 2. In addition, the switching source electrode SS may be electrically connected to the data line DL.

One side of the switching semiconductor layer SA may be electrically connected to the switching source electrode SS through a contact hole, and the other side of the switching semiconductor layer SA may be connected to the switching drain electrode SD through a contact hole.

The switching thin film transistor ST may be turned on or off by a scan signal supplied by the scan line SL. Therefore, when the data voltage is provided through the data line DL, the switching thin film transistor ST may control an application of the data voltage to the sub-pixel through the scan signal.

The driving thin film transistor DT may be disposed in an area overlapping the light shielding layer LS. The driving thin film transistor DT may drive the sub-pixel SP based on a signal applied by the switching thin film transistor ST.

The driving thin film transistor DT may include a driving gate electrode DG, a driving semiconductor layer DA, a driving source electrode DS, and a driving drain electrode DD. The driving gate electrode DG may be electrically connected to the switching drain electrode SD. As shown in FIG. 2, the driving gate electrode DG and the switching drain electrode SD may be continuously formed, but are not limited thereto. The driving source electrode DS may be electrically connected to a driving voltage line VDD, and the driving drain electrode DD may be electrically connected to the anode ANO.

One side of the driving semiconductor layer DA may be electrically connected to the driving source electrode DS through a contact hole, and the other side of the driving semiconductor layer DA may be connected to the driving drain electrode DD through a contact hole.

FIG. 2 discloses the switching thin film transistor ST and the driving thin film transistor DT having a top-gate structure, but is not limited thereto. Specifically, the driving gate electrode DG may be disposed on the driving semiconductor layer DA, and the switching gate electrode SG may be disposed on the switching semiconductor layer SA.

The capacitor electrode CE may be electrically connected to the switching drain electrode SD and the driving gate electrode DG. As shown in FIG. 2, the capacitor electrode CE may be continuously formed with the switching drain electrode SD and the driving gate electrode DG. That is, one side of the capacitor electrode CE may extend on the switching semiconductor layer SA to function as the switching drain electrode SD, and the other side of the capacitor electrode CE may extend on the driving semiconductor layer DA to function as the driving gate electrode DG.

The anode ANO may be disposed on the switching thin film transistor ST and the driving thin film transistor DT. The anode ANO may be electrically connected to the driving drain electrode DD. In addition, the anode ANO may overlap the capacitor electrode CE.

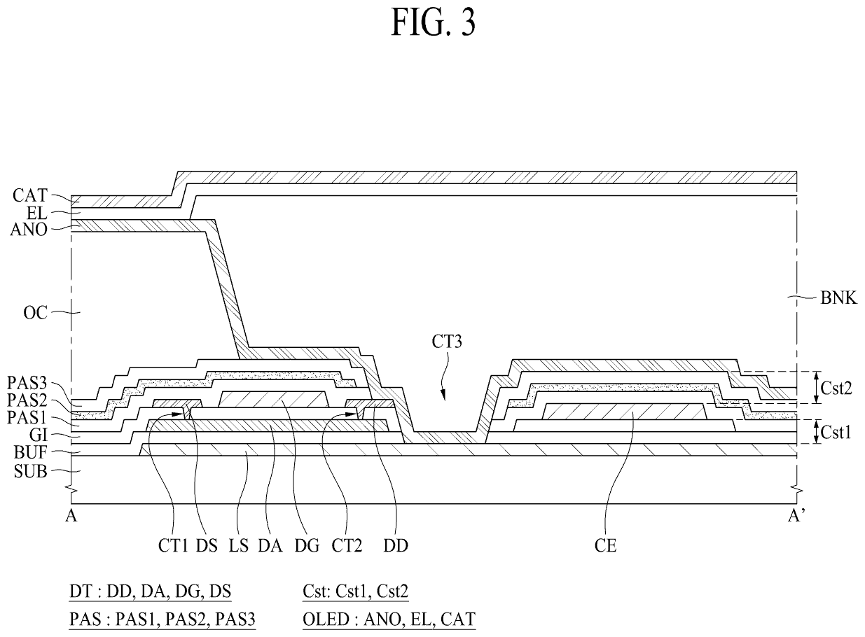

FIG. 3 is a cross-sectional view taken along line A-A′ in FIG. 2. Specifically, FIG. 3 is a cross-sectional view of the driving thin film transistor DT and the capacitor electrode CE.

As shown in FIG. 3, one sub-pixel SP may include a substrate SUB, a light shielding layer LS, a buffer layer BUF, a gate insulating layer GI, a driving thin film transistor DT, a capacitor electrode CE, a passivation layer PAS, a planarization layer OC, a bank BNK, and a light emitting device OLED.

The substrate SUB may be formed of glass or plastic, but is not limited thereto.

As described above with reference to FIG. 2, the light shielding layer LS may be disposed on the substrate SUB. The light shielding layer LS may prevent or protect the semiconductor layer SA of the switching thin film transistor ST and the semiconductor layer DA of the driving thin film transistor DT from being affected by external light.

The light shielding layer LS may include a conductive material capable of blocking light. For example, the light shielding layer LS may be formed of an opaque metal material such as aluminum (Al), silver (Ag), copper (Cu), molybdenum (Mo), titanium (Ti), tungsten (W), or chromium (Cr), or an alloy thereof. FIG. 3 illustrates that the light shielding layer LS is formed as a single layer, but is not limited thereto. For example, the light shielding layer LS may be formed of multiple layers.

The buffer layer BUF may be disposed on the substrate SUB and may cover the light shielding layer LS. The buffer layer BUF may include silicon nitride (SiNx) or silicon oxide (SiOx). Although shown as a single layer, the buffer layer BUF may be formed of multiple layers. The buffer layer BUF may insulate the light shielding layer LS and may improve adhesion between layers disposed on the buffer layer BUF and the substrate SUB.

The driving thin film transistor DT may be disposed on the buffer layer BUF. In addition, the driving thin film transistor DT may be disposed at a position overlapping the light shielding layer LS. Accordingly, since the light shielding layer LS is disposed under the driving thin film transistor DT, reliability of the driving thin film transistor DT may be improved by preventing or blocking external light from affecting the driving thin film transistor DT.

As described above, the driving thin film transistor DT may include a driving gate electrode DG, a driving semiconductor layer DA, a driving source electrode DS, and a driving drain electrode DD.

The driving semiconductor layer DA may be disposed on the buffer layer BUF. The driving semiconductor layer DA may include a poly-silicon semiconductor or an oxide semiconductor. In addition, where the driving semiconductor layer DA includes an oxide semiconductor, at least one oxide of indium-gallium-zinc-oxide (IGZO), indium-zinc-oxide (IZO), indium-gallium-tin-oxide (IGTO), and indium-gallium-oxide (IGO) may be included.

The gate insulating layer GI may be disposed between the driving semiconductor layer DA and the driving gate electrode DG. That is, the gate insulating layer GI may be disposed on the driving semiconductor layer DA, and the driving gate electrode DG may be disposed on the gate insulating layer GI. The driving semiconductor layer DA and the driving gate electrode DG may be insulated from each other by the gate insulating layer GI. The gate insulating layer GI may include silicon nitride (SiNx) or silicon oxide (SiOx). Although illustrated as a single layer, the gate insulating layer GI may be formed of multiple layers.

One side of the driving semiconductor layer DA may be electrically connected to the driving source electrode DS through a first contact hole CT1, and the other side of the driving semiconductor layer DA may be connected to the driving drain electrode DD through a second contact hole CT2. The first contact hole CT1 and the second contact hole CT2 may penetrate the gate insulating layer GI and expose the driving semiconductor layer DA.

The capacitor electrode CE may be disposed on the gate insulating layer GI. The capacitor electrode CE is disposed on the same layer as the driving gate electrode DG and may be formed by the same process as the driving gate electrode DG. In addition, the capacitor electrode CE may be electrically connected to the driving gate electrode DG. FIG. 2 illustrates that the capacitor electrode CE is continuously formed with the driving gate electrode DG, but is not limited thereto. For example, the capacitor electrode CE and the driving gate electrode DG may be electrically connected through a contact hole.

The passivation layer PAS may be disposed on the driving thin film transistor DT and the capacitor electrode CE. The passivation layer PAS may protect the driving thin film transistor DT and the capacitor electrode CE.

The passivation layer PAS may include a first passivation layer PAS1, a second passivation layer PAS2, and a third passivation layer PAS3.

The first passivation layer PAS1 may be disposed on the driving thin film transistor DT and the capacitor electrode CE. The first passivation layer PAS1 may cover the driving gate electrode DG and the capacitor electrode CE. The first passivation layer PAS1 may include an inorganic insulating material such as a silicon oxide layer (SiOx) or a silicon nitride layer (SiNx), but is not limited thereto.

The second passivation layer PAS2 may be disposed on the first passivation layer PAS1. The second passivation layer PAS2 may overlap the driving thin film transistor DT and the capacitor electrode CE. An area of a lower surface of the second passivation layer PAS2 may be smaller than an area of an upper surface of the first passivation layer PAS1. That is, a partial area of the upper surface of the first passivation layer PAS1 may be exposed by the second passivation layer PAS2. In addition, the second passivation layer PAS2 may include a semiconductor material such as amorphous silicon, but is not limited thereto.

The third passivation layer PAS3 may be disposed on the second passivation layer PAS2. The third passivation layer PAS3 may overlap the driving thin film transistor DT and the capacitor electrode CE. The third passivation layer PAS3 may cover an entire upper and side surfaces of the second passivation layer PAS2. In addition, the third passivation layer PAS3 may cover the upper surface of the first passivation layer PAS1 exposed by the second passivation layer PAS2. That is, the second passivation layer PAS2 may be shielded by the first passivation layer PAS1 and the third passivation layer PAS3, and the second passivation layer PAS2 may not be exposed to the outside. Accordingly, an influence of the second passivation layer PAS2 made of a semiconductor material on the driving semiconductor layer DA and the driving gate electrode DG is minimized or reduced, and thus the driving thin film transistor DT may be stably or more stably driven.

The third passivation layer PAS3 may include an inorganic insulating material such as a silicon oxide film (SiOx) or a silicon nitride film (SiNx), but is not limited thereto. In addition, the first passivation layer PAS1 and the third passivation layer PAS3 may include the same material. Alternatively, the first passivation layer PAS1 and the third passivation layer PAS3 may include different materials. For example, the first passivation layer PAS1 may include a silicon nitride film (SiNx), and the third passivation layer PAS3 may include a silicon oxide film (SiOx).

The planarization layer OC may be disposed on the third passivation layer PAS3. The planarization layer OC may cover a partial area of the driving thin film transistor DT. In addition, the planarization layer OC may not overlap the capacitor electrode CE.

The planarization layer OC may be formed of an organic insulating material such as an acrylic resin, an epoxy resin, a phenolic resin, a polyamide resin, or a polyimide resin.

The light emitting device OLED may be disposed on the planarization layer OC. The light emitting device OLED may include an anode ANO, a light emitting layer EL, and a cathode CAT.

The anode ANO may be disposed on the planarization layer OC. The anode ANO may extend on the planarization layer OC and may also be disposed on the third passivation layer PAS3.

The anode ANO may be electrically connected to the driving drain electrode DD and the light shielding layer LS through a third contact hole CT3. That is, the anode ANO may be electrically connected to the driving drain electrode DD and the light shielding layer LS simultaneously through one third contact hole CT3. The third contact hole CT3 may penetrate the passivation layer PAS, the gate insulating layer GI and the buffer layer BUF, and may expose the driving drain electrode DD and the light shielding layer LS.

In particular, the third contact hole CT3 may penetrate the first passivation layer PAS1 and the third passivation layer PAS3, and may not penetrate the second passivation layer PAS2. That is, a side surface of the third contact hole CT3 may include a side surface of the first passivation layer PAS1 and a side surface of the third passivation layer PAS3, and may not include a side surface of the second passivation layer PAS2. Accordingly, the second passivation layer PAS2 may not be exposed to the outside.

Meanwhile, compared to a conventional structure in which a passivation layer having a single layer is disclosed, the present disclosure discloses a passivation layer PAS having a triple layer, and thus the passivation layer PAS may be formed relatively thick. Accordingly, in a process of forming the third contact hole CT3, it is possible to prevent or suppress the passivation layer PAS from being spaced apart from a lower layer or a crack from the side surface of the passivation layer PAS.

The anode ANO may include a transparent conductive material such as indium tin oxide (ITO) or indium zinc oxide (IZO). Alternatively, the anode ANO may include a metal material such as aluminum (Al), silver (Ag), copper (Cu), molybdenum (Mo), titanium (Ti), tungsten (W), or chromium (Cr), or an alloy thereof. Further, the anode ANO is illustrated as a single layer, but may be formed as multiple layers.

The bank BNK may be disposed on the planarization layer OC and the third passivation layer PAS3. The bank BNK may expose a partial area of the anode ANO. An area in which the anode ANO is exposed by the bank BNK may function as a light emitting area of the sub-pixel SP. In addition, the bank BNK may fill an inside of the third contact hole CT3.

The bank BNK may include an organic insulating material such as an acrylic resin, an epoxy resin, a phenolic resin, a polyamide resin, a polyimide resin, etc. Alternatively, the bank BNK may include an inorganic insulating material such as silicon oxide (SiOx), silicon nitride (SiNx), silicon oxynitride (SiOxNy), etc. In this case, the bank BNK may further include a material absorbing light. For example, the bank BNK may be a black bank.

The light emitting layer EL may be disposed on the anode ANO. The light emitting layer EL may also be disposed on a bank BNK. The light emitting layer EL may include a hole transporting layer, an emission layer, and an electron transporting layer. In this case, when a voltage is applied to the anode ANO and the cathode CAT, holes and electrons move to the emission layer through the hole transport layer and the electron transport layer, respectively, and holes and electrons may combine with each other in the emission layer to emit light.

The cathode CAT may be disposed on the light emitting layer EL. The cathode CAT may also be disposed on the bank BNK.

Since the display device according to an example embodiment of the present disclosure is configured in a top emission type, the cathode CAT may include a transparent conductive material such as an indium tin oxide (ITO) or an indium zinc oxide (IZO) to transmit light emitted from the light emitting layer EL to the top.

Meanwhile, since the light shielding layer LS is electrically connected to the anode ANO, the light shielding layer LS may function as an electrode. In addition, since the capacitor electrode CE is electrically connected to the driving gate electrode DG, the capacitor electrode CE may function as an electrode. Accordingly, a plurality of storage capacitors Cst may be formed by the light shielding layer LS, the capacitor electrode CE, and the anode ANO.

The plurality of storage capacitors Cst may include a first storage capacitor Cst1 and a second storage capacitor Cst2. The first storage capacitor Cst1 may include the light shielding layer LS, the capacitor electrode CE, and a first dielectric layer disposed between the light shielding layer LS and the capacitor electrode CE. In this case, the first dielectric layer may include the buffer layer BUF and the gate insulating layer GI. In addition, the second storage capacitor Cst2 may include the capacitor electrode CE, the anode ANO, and a second dielectric layer disposed between the capacitor electrode CE and the anode ANO. In this case, the second dielectric layer may include the first passivation layer PAS1, the second passivation layer PAS2, and the third passivation layer PAS3.

As described above, the second passivation layer PAS2 includes a semiconductor material such as amorphous silicon, and the first passivation layer PAS1 and the third passivation layer PAS3 may include an inorganic insulating material such as a silicon oxide film (SiOx) or a silicon nitride film (SiNx). Accordingly, a dielectric constant of the second passivation layer PAS2 may be higher than a dielectric constant of each of the first passivation layer PAS1 and the third passivation layer PAS3. Accordingly, compared to a conventional structure in which a passivation layer including only an inorganic insulating material is disclosed, the present disclosure additionally discloses the second passivation layer PAS2 including a semiconductor material such as amorphous silicon, and thus, the dielectric constant of the passivation layer PAS may be increased. Accordingly, a capacity of the second storage capacitor Cst2 may be further increased.

In addition, as described above, the second passivation layer PAS2 may not be exposed to the outside by the first passivation layer PAS1 and the third passivation layer PAS3. Accordingly, while the second passivation layer PAS2 is stably formed, the dielectric constant of the passivation layer PAS may be increased.

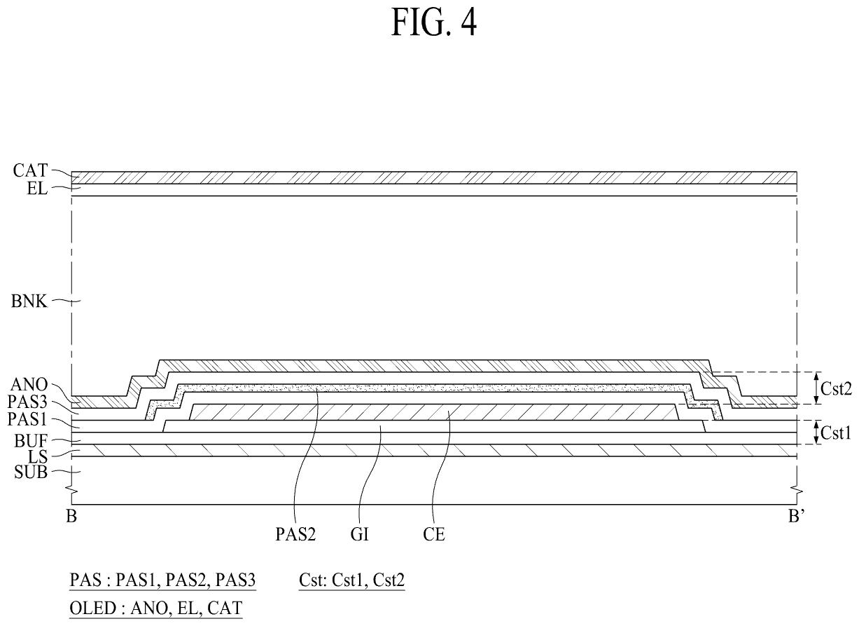

FIG. 4 is a cross-sectional view taken along line B-B′ in FIG. 2. Specifically, a cross-sectional view of the capacitor electrode CE is illustrated.

As described above, the capacitor electrode CE may be disposed on the gate insulating layer GI. An area of a lower surface of the capacitor electrode CE may be smaller than an area of an upper surface of the gate insulating layer GI, but is not limited thereto. For example, the capacitor electrode CE may cover the entire upper surface of the gate insulating layer GI.

The passivation layer PAS may be disposed on the capacitor electrode CE. The passivation layer PAS may include a first passivation layer PAS1, a second passivation layer PAS2, and a third passivation layer PAS3.

The first passivation layer PAS1 may be disposed on the capacitor electrode CE. The first passivation layer PAS1 may cover upper and side surfaces of the capacitor electrode CE. In addition, the first passivation layer PAS1 may extend from the upper surface of the capacitor electrode CE to cover upper and side surfaces of the gate insulating layer GI.

The second passivation layer PAS2 may be disposed on the first passivation layer PAS1. The second passivation layer PAS2 may overlap the entire upper surface of the capacitor electrode CE. In addition, the second passivation layer PAS2 may overlap the side surface of the capacitor electrode CE. An area of the lower surface of the second passivation layer PAS2 may be smaller than an area of the upper surface of the first passivation layer PAS1. That is, a partial area of the upper surface of the first passivation layer PAS1 may be exposed by the second passivation layer PAS2. In addition, an end of the second passivation layer PAS2 may be disposed on the upper surface of the first passivation layer PAS1.

The third passivation layer PAS3 may be disposed on the second passivation layer PAS2. The third passivation layer PAS3 may cover the entire upper and side surfaces of the second passivation layer PAS2. That is, the third passivation layer PAS3 may cover an end of the second passivation layer PAS2. In addition, the third passivation layer PAS3 may cover the upper surface of the first passivation layer PAS1 exposed by the second passivation layer PAS2.

Accordingly, a partial area of the passivation layer PAS may have a stack structure in which the first passivation layer PAS1, the second passivation layer PAS2, and the third passivation layer PAS3 are sequentially disposed, and a remaining area of the passivation layer PAS may have a stack structure in which the first passivation layer PAS1 and the third passivation layer PAS3 are sequentially disposed. Particularly, in an area overlapping the capacitor electrode CE, the passivation layer PAS may have a stack structure of the first passivation layer PAS1, the second passivation layer PAS2, and the third passivation layer PAS3.

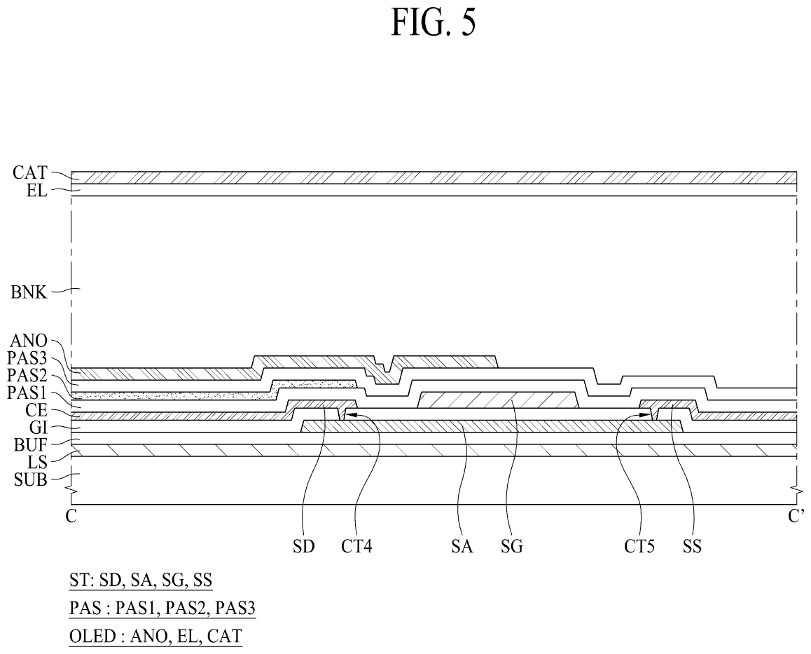

FIG. 5 is a cross-sectional view taken along line C-C′ in FIG. 2. Specifically, FIG. 5 illustrates a cross-sectional view of the capacitor electrode CE and the switching thin film transistor ST.

As shown in FIG. 5, the light shielding layer LS may be disposed on the substrate SUB, and the buffer layer BUF may be disposed on the light shielding layer LS.

The switching thin film transistor ST may be disposed on the buffer layer BUF. In addition, the switching thin film transistor ST may be disposed at a position overlapping the light shielding layer LS. Accordingly, since the light shielding layer LS is disposed under the switching thin film transistor ST, the reliability of the switching thin film transistor ST may be improved by preventing or blocking external light from affecting the switching thin film transistor ST.

As described above, the switching thin film transistor ST may include a switching gate electrode SG, a switching semiconductor layer SA, a switching source electrode SS, and a switching drain electrode SD.

The switching semiconductor layer SA may be disposed on the buffer layer BUF. The switching semiconductor layer SA may include a poly-silicon semiconductor or an oxide semiconductor. Also, where the switching semiconductor layer SA includes an oxide semiconductor, at least one oxide of indium-gallium-zinc-oxide (IGZO), indium-zinc-oxide (IZO), indium-gallium-tin-oxide (IGTO), and indium-gallium-oxide (IGO) may be included.

A gate insulating layer GI may be disposed between the switching semiconductor layer SA and the switching gate electrode SG. That is, the gate insulating layer GI may be disposed on the switching semiconductor layer SA, and the switching gate electrode SG may be disposed on the gate insulating layer GI. The switching semiconductor layer SA and the switching gate electrode SG may be insulated from each other by the gate insulating layer GI. The gate insulating layer GI may include silicon nitride (SiNx) or silicon oxide (SiOx). Although illustrated as a single layer, the gate insulating layer GI may be formed of multiple layers.

One side of the switching semiconductor layer SA may be electrically connected to the switching drain electrode SD through a fourth contact hole CT4, and the other side of the switching semiconductor layer SA may be connected to the switching source electrode SS through a fifth contact hole CT5. The fourth contact hole CT4 and the fifth contact hole CT5 may penetrate the gate insulating layer GI and expose the switching semiconductor layer SA.

The capacitor electrode CE may be disposed on the gate insulating layer GI. The capacitor electrode CE is disposed on the same layer as the switching drain electrode SD and may be formed by the same process as the switching drain electrode SD. In addition, the capacitor electrode CE may be electrically connected to the switching drain electrode SD. FIG. 5 illustrates that the capacitor electrode CE is continuously formed with the switching drain electrode SD, but is not limited thereto. For example, the capacitor electrode CE and the switching drain electrode SD may be electrically connected through a contact hole.

The passivation layer PAS may be disposed on the switching thin film transistor ST and the capacitor electrode CE. The passivation layer PAS may protect the switching thin film transistor ST and the capacitor electrode CE.

As described above, the passivation layer PAS may include a first passivation layer PAS1, a second passivation layer PAS2, and a third passivation layer PAS3.

The first passivation layer PAS1 may be disposed on the switching thin film transistor ST and the capacitor electrode CE. The first passivation layer PAS1 may cover the switching gate electrode SG and the capacitor electrode CE.

The second passivation layer PAS2 may be disposed on the first passivation layer PAS1. The second passivation layer PAS2 may overlap the capacitor electrode CE. In addition, the second passivation layer PAS2 may overlap the switching drain electrode SD.

The third passivation layer PAS3 may be disposed on the second passivation layer PAS2. The third passivation layer PAS3 may cover the entire upper and side surfaces of the second passivation layer PAS2. In addition, the third passivation layer PAS3 may cover the upper surface of the first passivation layer PAS1 exposed by the second passivation layer PAS2. That is, the second passivation layer PAS2 may be shielded by the first passivation layer PAS1 and the third passivation layer PAS3, and the second passivation layer PAS2 may not be exposed to the outside. Accordingly, the influence of the second passivation layer PAS2 formed of a semiconductor material on the switching semiconductor layer SA and the switching gate electrode SG is minimized or reduced, and thus the switching thin film transistor ST may be stably or more stably driven.

It will be apparent to those skilled in the art that the present disclosure described above is not limited by the above-described example embodiments and the accompanying drawings and that various substitutions, modifications, and variations can be made in the present disclosure without departing from the spirit or scope of the disclosures. Consequently, a protected scope of the present disclosure may be defined by the accompanying claims and their equivalents, and it is intended that all variations or modifications derived from the meaning, scope, and equivalent concept of the claims fall within the scope of the present disclosure.

What is claimed is:

1. A display device, comprising:
a light shielding layer on a substrate;
a driving thin film transistor on the light shielding layer; and
a passivation layer on the driving thin film transistor, the passivation layer including:
a first passivation layer on the driving thin film transistor;
a second passivation layer on the first passivation layer; and
a third passivation layer on the second passivation layer,
wherein the second passivation layer is not exposed to an outside by the first passivation layer and the third passivation layer, and
wherein a dielectric constant of the second passivation layer is higher than a dielectric constant of each of the first passivation layer and the third passivation layer.

2. The display device of claim 1, wherein:
each of the first passivation layer and the third passivation layer includes an inorganic insulating material; and
the second passivation layer includes a semiconductor material.

3. The display device of claim 1, wherein the third passivation layer covers entire upper and side surfaces of the second passivation layer.

4. The display device of claim 1, wherein the second passivation layer exposes a part of an upper surface of the first passivation layer, and the third passivation layer covers an upper surface of the first passivation layer exposed by the second passivation layer.

5. The display device of claim 1, wherein an end of the second passivation layer is disposed on an upper surface of the first passivation layer, and the third passivation layer covers an end of the second passivation layer.

6. The display device of claim 1, wherein:
a partial area of the passivation layer includes a structure in which the first passivation layer, the second passivation layer, and the third passivation layer are sequentially stacked; and
a remaining area of the passivation layer includes a structure in which the first passivation layer and the third passivation layer are sequentially stacked.

7. The display device of claim 1, further comprising a capacitor electrode between the light shielding layer and the first passivation layer,
wherein the capacitor electrode is disposed on a same layer as a gate electrode of the driving thin film transistor, and the capacitor electrode is electrically connected to the gate electrode of the driving thin film transistor.

8. The display device of claim 7, wherein the first passivation layer covers entire upper and side surfaces of the capacitor electrode.

9. The display device of claim 7, wherein the second passivation layer overlaps the capacitor electrode.

10. The display device of claim 7, wherein the passivation layer includes a structure in which the first passivation layer, the second passivation layer, and the third passivation layer are sequentially stacked in an area overlapping the capacitor electrode.

11. The display device of claim 7, further comprising an anode on the passivation layer, and
wherein the anode is electrically connected to the driving thin film transistor and the light shielding layer.

12. The display device of claim 11, wherein the anode is electrically connected to both the driving thin film transistor and the light shielding layer through one contact hole.

13. The display device of claim 12, wherein the contact hole penetrates the first passivation layer and the third passivation layer, and does not penetrate the second passivation layer.

14. The display device of claim 13, wherein a side surface of the contact hole includes a side surface of the first passivation layer and a side surface of the third passivation layer, and does not include a side surface of the second passivation layer.

15. The display device of claim 2, wherein:
the inorganic insulating material includes a silicon oxide layer or a silicon nitride layer, and/or
the semiconductor material includes amorphous silicon.
